(19) United States
(12) Patent Application Publication
(10) Pub. No.: US 2025/0175279 A1
(43) Pub. Date: May 29, 2025

(54) METHOD FOR IMPROVING POLAR CODE PERFORMANCE USING LOCAL PRE-TRANSFORMATION

(71) Applicant: KOREA UNIVERSITY RESEARCH AND BUSINESS FOUNDATION, Seoul (KR)

(72) Inventors: Nam Yoon LEE, Seoul (KR); Geon Choi, Seoul (KR)

(73) Assignee: KOREA UNIVERSITY RESEARCH AND BUSINESS FOUNDATION, Seoul (KR)

(21) Appl. No.: 18/963,862

(22) Filed: Nov. 29, 2024

(30) Foreign Application Priority Data
Nov. 28, 2023 (KR) 10-2023-0168015
Jan. 3, 2024 (KR) 10-2024-0000874

(51) Int. Cl. H04L 1/00

(52) U.S. Cl. CPC H04L 1/0041; H04L 1/0045; H04L 1/0057

(57) ABSTRACT

An encoder using local pre-transformation is provided. According to an embodiment, the encoder may include a bit splitting unit configured to generate a specific information signal and remaining information signals by splitting an input signal, a pre-transform unit configured to generate connection signals by performing, in parallel, local pre-transformation, based on each of the remaining information signals, and a polar transform unit configured to generate an output signal by performing polar transformation, based on the specific information signal and the connection signals.

### CROSS-REFERENCE TO RELATED APPLICATIONS

This application claims priority under 35 U.S.C. § 119 to Korean Patent Application No. 10-2023-0168015 filed on Nov. 28, 2023 and Korean Patent Application No. 10-2024-0000874 filed on Jan. 3, 2024 in the Korean Intellectual Property Office, the disclosures of which are incorporated by reference herein in their entirety.

### TECHNICAL FIELD

The present disclosure relates to channel coding, and more particularly, to a method of improving polar code performance by using local pre-transformation, and a system using the method.

The present research was performed with the support of the Samsung Science & Technology Foundation (Task No. SRFC-IT2302-04).

### BACKGROUND

There is continuing demand for ultra-reliable low-latency communication (URLLC) in the next-generation wireless communication systems. The URLLC focuses on achieving ultra-high-speed data packet transmission within a very short time period, for example, 1 ms, while guaranteeing the reliability of a packet error rate (PER) of less than 10⁻⁵. To this end, it is important to develop state-of-the art channel coding techniques for executing optimal performance within the range of a finite block-length (FBL).

Polar codes are one of the channel codes for achieving channel capacity within the range of an infinite block-length (IBL). When a code for pre-transformation is configured in the polar codes, a channel polarization-based decoder commonly used in the polar codes may undergo a deterioration in performance.

### SUMMARY

It is important to configure the pre-transformation of polar codes appropriate for a channel-polarization-based decoder.

In order to achieve the technical objective described above, an encoder using local pre-transformation is disclosed according to the inventive concept of the present disclosure.

The encoder may include a bit splitting unit configured to generate a specific information signal and remaining information signals by splitting an input signal. The encoder may include a pre-transform unit configured to generate connection signals by performing, in parallel, local pre-transformation, based on each of the remaining information signals. The encoder may include a polar transform unit configured to generate an output signal by performing polar transformation, based on the specific information signal and the connection signals.

According to an embodiment, the polar transform unit may further be configured to perform the polar transformation, based on the specific information signal, and non-consecutive information bits of the connection signals and to obtain the output signal from a result of the polar transformation.

According to an embodiment, a number of consecutive information bits of the connection signals may be limited based on a size of each connection signal.

According to an embodiment, the pre-transform unit may include local pre-transform units, and each of the local pre-transform units may be configured to generate the connection signal by performing the local pre-transformation using an upper-triangular matrix, based on a corresponding remaining information signal.

According to an embodiment, the pre-transform unit may include local pre-transform units, and each of the local pre-transform units may be configured to generate a pre-transform input signal by adding one or more frozen bits to a corresponding remaining information signal and to generate the connection signal by performing the local pre-transformation on the pre-transform input signal.

According to an embodiment, as the one or more frozen bits are added to the corresponding remaining information signal, the connection signal may include non-consecutive information bits.

According to an embodiment, each of the local pre-transform units may be further configured to assign the corresponding remaining information signal to one or more elements of the pre-transform input signal indicated by a corresponding information index set and to assign the one or more frozen bits to one or more remaining elements of the pre-transform input signal.

According to an embodiment, the polar transform unit may further be configured to generate a polar transform input signal including the specific information signal, the connection signals, and one or more frozen bits and to generate the output signal by performing polar transformation on the polar transform input signal.

According to an embodiment, the polar transform unit may further be configured to assign the specific information signal to one or more elements of the polar transform input signal indicated by a corresponding information index set, assign a corresponding connection signal to one or more elements of the polar transform input signal indicated by a connection index set, and assign the one or more frozen bits to one or more remaining elements of the polar transform input signal.

According to an embodiment, the information index set and the connection index set may include, from among total indices of the polar transform input signal, indices having high channel reliability and having a corresponding row-weight of a polar transformation matrix greater than or equal to a predetermined threshold value.

In order to achieve the technical objective described above, an encoding method using local pre-transformation is disclosed according to the inventive concept of the present disclosure.

The encoding method may include generating a specific information signal and remaining information signals by splitting an input signal. The encoding method may include generating connection signals by performing, in parallel, local pre-transformation, based on each of the remaining information signals. The encoding method may include generating an output signal by performing polar transformation, based on the specific information signal and the connection signals.

According to an embodiment, the generating of the output signal may include performing the polar transformation, based on the specific information signal and non-consecutive information bits of the connection signals, and obtaining the output signal from a result of the polar transformation.

According to an embodiment, a number of consecutive information bits of the connection signals may be limited based on a size of each connection signal.

According to an embodiment, the generating of the connection signals may include obtaining the connection signals by performing, in parallel, the local pre-transformation using an upper-triangular matrix, based on each of the remaining information signals.

According to an embodiment, the generating of the connection signals may include generating pre-transform input signals by adding one or more frozen bits to the remaining information signals, respectively, and generating the connection signals by performing, in parallel, the local pre- transformation on each of the pre-transform input signals.

According to an embodiment, as the one or more frozen bits are added to the remaining information signals, respectively, the connection signals may include non-consecutive information bits, respectively.

According to an embodiment, the generating of the pre-transform input signals may include assigning a corresponding remaining information signal to one or more elements of a pre-transform input signal indicated by a corresponding information index set and assigning the one or more frozen bits to one or more remaining elements of the pre-transform input signal.

According to an embodiment, the generating of the output signal may include generating a polar transform input signal including the specific information signal, the connection signals, and one or more frozen bits and generating the output signal by performing polar transformation on the polar transform input signal.

According to an embodiment, the generating of the polar transform input signal may include assigning the specific information signal to one or more elements of the polar transform input signal indicated by a corresponding information index set, assigning a corresponding connection signal to one or more elements of the polar transform input signal indicated by a connection index set, and assigning the one or more frozen bits to one or more remaining elements of the polar transform input signal.

In order to achieve the technical objective described above, a decoding method is disclosed according to the inventive concept of the present disclosure.

The decoding method may include receiving an input signal and generating an output signal corresponding to the input signal by sequentially searching for decoding paths with respect to the input signal and selecting a final decoding path from among the decoding paths.

According to an embodiment, a number of the decoding paths may not exceed a predetermined number.

According to an embodiment, the input signal may correspond to a codeword encoded based on parallel local pre-transformation and polar transformation.

### BRIEF DESCRIPTION OF THE FIGURES

FIG. 1 illustrates a channel coding system according to an embodiment.

FIG. 2 illustrates a structure of an encoder according to an embodiment.

FIG. 3 illustrates a decoding process according to an embodiment.

### DETAILED DESCRIPTION

Advantages and the characteristics of the disclosed embodiment and methods of achieving the same will be apparent with reference to embodiments described below together with the accompanying drawings. However, the present disclosure is not limited to the embodiments disclosed hereinafter. Rather, the present disclosure may be realized in various different forms, and the present embodiments may be merely given to completely explain the present disclosure and help one of ordinary skill in the art fully understand the scope of the disclosure.

It will be understood that each block of a flowchart may be performed by computer program instructions. These computer program instructions may be loaded on a processor of a general-purpose computer, a special-use computer, or other programmable data processing devices, and thus, instructions performed by the processor of the computers or the other programmable data processing devices may generate a device for performing the functions described in the block(s). These computer program instructions may also be stored in a computer-usable or computer-readable memory which may be oriented for a computer or other programmable data processing devices in order to realize the functions in a specific method. Thus, the instructions stored in the computer-usable or the computer-readable memory may also generate a manufacturing item including the instruction device for performing the functions described in the block(s). The computer program instructions may be loaded on a computer or other programmable data processing devices, and thus, a series of operations may be performed on the computer or the other programmable data processing devices to generate a process executed on the computer, so that the instructions performed by the computer or the other programmable data processing devices may provide operations for performing the functions described with reference to the block(s). Also, each block may represent part of a module, a segment, or a code including one or more executable instructions for performing (a) specific logic function(s).

The terms used in this specification will be briefly described, and the disclosed embodiment will be described in detail.

The terms used herein are selected as general terms as currently widely used as possible while taking into account the functions in the present disclosure, which, however, may be changed according to an intention of a technician in the art, a precedent, the advent of new technologies, or the like. Also, in particular cases, there may be terms arbitrarily selected by the applicant. In this case, their meanings will be described in detail in corresponding description parts of the disclosure. Therefore, the terms used in the present disclosure shall be defined based on the meanings of the terms and the content throughout the present disclosure, rather than simply based on the titles of the terms.

In the present disclosure, for convenience of explanation, the lower suffix notation indicating vector indexing is used. For example, when a vector u=[1,3,2,4,5] and a set A={2,4} for indexing are given, u_{A}=[u₂,u₄]=[3,4] in the vector indexing using the lower suffix notation.

In the present disclosure, for brevity, with respect to a<b, U_{a:b}=[Uₐ, Uₐ₊₁, . . . , U_{b}].

Throughout the present disclosure, the expression “at least one of a, b or c” may indicate “a,” “b,” “c,” “a and b,” “a and c,” “b and c,” “all of a, b, and c,” or variations thereof.

Singular expressions in the present specification include plural expressions unless the context clearly indicates singular forms.

Throughout the specification, when a part “includes” an element, the part may further include other elements, rather than excluding other elements, unless there is a particular description contrary thereto.

Also, the term “unit” used in the specification denotes a software or hardware component and the “unit” performs certain functions. However, the meaning of the term “unit” is not limited to software or hardware. A “unit” may be configured to be in a storage medium which may be addressed or may be configured to play one or more processors. Thus, for example, a “unit” may include components, such as software components, object-oriented software components, class components, and task components, processes, functions, attributes, procedures, sub-routines, segments of a program code, drivers, firmware, a microcode, a circuit, data, a database, data structures, tables, arrays, and variables. Functions provided by the components and the “units” may be combined into a reduced number of components or “units” or may further be divided into additional components and “units.”

The term “processor” should be widely interpreted as including a general-purpose processor, a central processing unit (CPU), a microprocessor, a digital signal processor (DSP), a controller, a microcontroller, a state machine, etc. In some environments, the “processor” may also refer to an application specific integrated circuit (ASIC), a programmable logic device (PLD), a field-programmable gate array (FPGA), etc. The term “processor” may also refer to, for example, a combination of a DSP and a microprocessor, a combination of a plurality of microprocessors, a combination of one or more microprocessors combined with a DSP core, or a combination of processing devices, such a combination of other such arbitrary components.

The term “memory” should be widely interpreted as including an arbitrary electronic component capable of storing electronic information. Also, the term memory may refer to various types of processor-readable media, such as a random-access memory (RAM), a read-only memory (ROM), a nonvolatile RAM (NVRAM), a programmable ROM (PROM), an erasable-PROM (EPROM), an electrically EPROM (EEPROM), a flash memory, a magnetic or optical data storage, registers, etc. When a processor is to read and/or record information from and/or in the memory, the memory may be referred to as being in an electronic communication state with the processor. The memory integrated into the processor may be in an electronic communication state with the processor.

Various embodiments of the present disclosure are described with reference to the accompanying drawings.

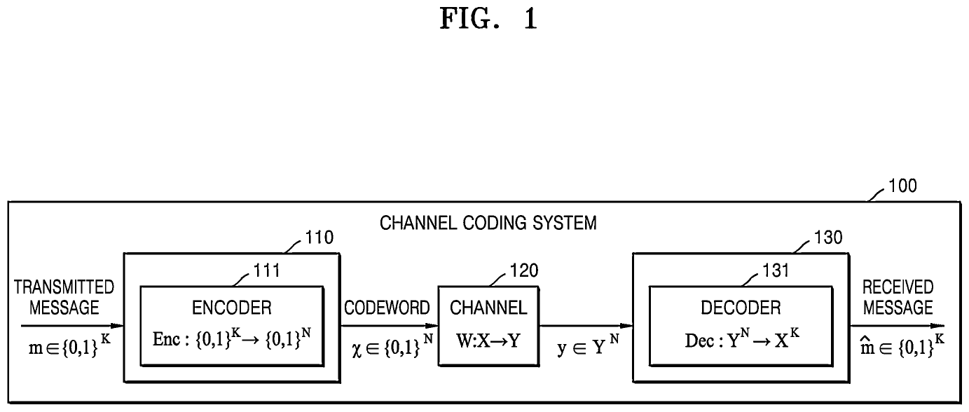

FIG. 1 illustrates a channel coding system 100 according to an embodiment.

It is important to configure a system such that a transmitted message m and a received message \hat{m} are the same as each other in the channel coding system 100. To this end, a transmitter 110 may generate a codeword x by performing channel encoding for more reliably transmitting the transmitted message m and transmit the codeword x through a channel 120 W:X→Y. Also, a receiver 130 may receive a codeword y including noise and perform channel decoding to reconstruct the received message \hat{m}.

An encoder 111 may encode the transmitted message m of K bits to generate the codeword x of N bits. The length of the codeword x may be increased by inserting appropriate parity bits into the transmitted message m. The parity bits may help the receiver 130 smoothly reconstruct the received message \hat{m}.

The transmitted message m may be represented by Equation 1.

$$m = [ {m}_{1} , {m}_{2} , … , {m}_{K} ] ∈ {\{ 0 , 1 \}}^{K} \qquad [ Equation 1 ]$$

where, with respect to k∈K, mₖ is an independent and uniformly distributed random variable with respect to {0,1}. {0,1}^{K} is a set having binary numbers from 0 to 2^{K}−1 as elements. For example, {0,1}²={00, 01, 10, 11}.

The codeword x may be represented by Equation 2.

$$x = [ {x}_{1} , {x}_{2} , … , {x}_{N} ] \qquad [ Equation 2 ]$$

Code rate is defined as a ratio of transmitted information bits to a code block length. According to an embodiment, the code rate is K/N.

The codeword x may pass the channel 120. Types of the channel 120 may vary. For example, the channel 120 may include a channel for wireless communication, wired communication, communication between a base station and an end system, communication of an electronic device, or communication of a chip (or a chiplet), but is not limited thereto. For example, the channel 120 may include a memoryless channel (MC), a discrete memoryless channel (DMC), or a binary-discrete memoryless channel (B- DMC), but is not limited thereto.

An output sequence y (that is, the codeword having passed the channel) of the channel 120 may be represented by Equation 3.

$$y = [ {y}_{1} , {y}_{2} , … , {y}_{N} ] \qquad [ Equation 3 ]$$

A decoder 131 may decode the codeword y to generate the received message (\hat{m}) of K bits. The decoder 131 may be designed to minimize a block error rate (BLER). Here, the BLER may denote a ratio of the number of error blocks to the total number of transmitted blocks.

With respect to the channel 120 W:X→Y, a channel capacity I(W) and a Bhattacharyya parameter Z(W) may be used as channel parameters related to the BLER.

When the channel 120 W:X→Y is a B-DMC, the channel capacity I(W) may be represented by Equation 4.

$$I ( W ) ≐ {\sum }_{{x}_{i} ∈ X} {\sum }_{{y}_{i} ∈ Y} \frac{1}{2} W ( {y}_{i} \vert {x}_{i} ) {log}_{2} \frac{W ( {y}_{i} \vert {x}_{i} )}{\frac{1}{2} W ( {y}_{i} \vert 0 ) + \frac{1}{2} W ( {y}_{i} \vert 1 )} \qquad [ Equation 4 ]$$

Also, the Bhattacharyya parameter Z(W) may be represented by Equation 5.

$$Z ( W ) ≐ {\sum }_{{y}_{i} ∈ Y} \sqrt{W ( {y}_{i} \vert 0 ) W ( {y}_{i} \vert 1 )} \qquad [ Equation 5 ]$$

where, X indicates a binary alphabet, and Y indicates an arbitrary alphabet. W(y|x) indicates a transition probability of the channel W with respect to an input x and an output y.

The BLER is related to the channel reliability. As the channel reliability increases, the BLER may decrease. Also, in contrast, as the channel reliability decreases, the BLER may increase. The channel capacity I(W) is a parameter related to a maximum transmission amount which may be transmitted with a high reliability in a channel, and as the channel capacity I(W) increases, the BLER may decrease to increase the channel reliability. Also, the Bhattacharyya parameter Z(W) is a parameter related to an error probability of a channel, and as the Bhattacharyya parameter Z(W) decreases, the BLER may decrease to increase the channel reliability.

A minimum distance d^{min} of a linear block code C may be represented by Equation 6.

$${d}^{min} ≐ {min}_{x ∈ C} wt ( x ) \qquad [ Equation 6 ]$$

where, [symbol] t(x)≐∥x∥₀, that is, the number of “1” in the vector x.

A weight spectrum A(C) of the linear block code C may be represented by Equation 7.

$$A ( C ) ≐ \{ ( d , {A}_{d} ) : 0 \leq d \leq N , {A}_{d} = \vert {C}_{d} \vert \} \qquad [ Equation 7 ]$$

where, C_{d}≐{x∈C: [symbol] t(x)=d}.

The minimum distance d^{min} and the number of minimum-weight codewords A_{d}^{min} may play an important role for determining the performance of maximum likelihood (ML) decoding. The code performance may be improved by increasing the minimum distance d^{min} while decreasing the number of minimum-weight codewords A_{d}^{min}.

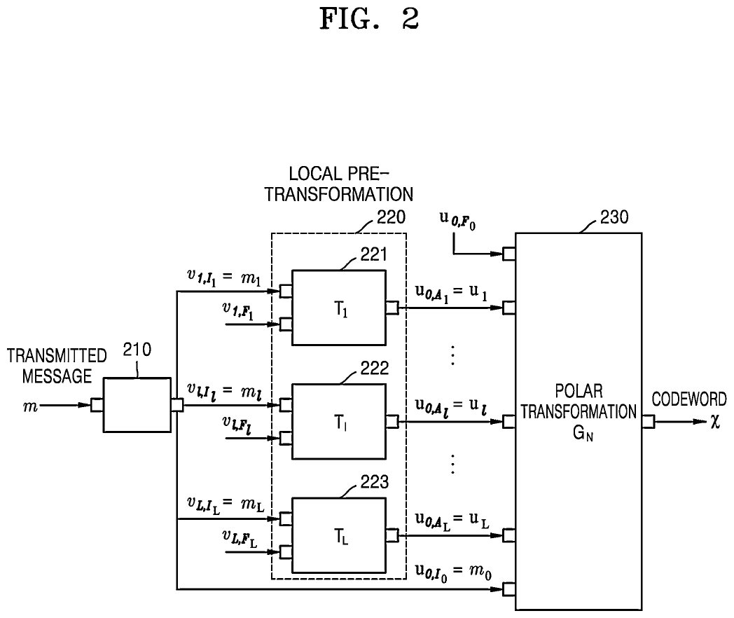

FIG. 2 illustrates a structure of an encoder according to an embodiment.

The encoder may include a bit splitting unit 210, a pre-transform unit 220, and a polar transform unit 230. The bit splitting unit 210 may generate a specific information signal m⁰ and remaining information signals m₁, . . . , and m_{L} by splitting an input signal m. The pre-transform unit 220 may perform local pre-transformation in parallel based on each of the remaining information signals m₁, . . . , and m_{L} to generate connection signals u₁, . . . , and u_{L}. The polar transform unit 230 may perform polar transformation based on the specific information signal m₀ and the connection signals u₁, . . . , and u_{L} to generate an output signal x.

The input signal m of the encoder may be the transmitted message m. The input signal m may be an information vector and may include K information bits.

The output signal x of the encoder may be the codeword x. The length of the output signal x may be N.

The bit splitting unit 210 may split the input signal m into L+1 information signals m₀, m₁, . . . , and m_{L}. From among the L+1 information signals, one information signal may be referred to as the specific information signal m₀, and L remaining information signals may be referred to as the remaining information signals m₁, . . . , and m_{L}. Each of the specific information signal m₀ and the remaining information signals m₁, . . . , and m_{L} may include one or more information bits.

For I∈{0,1, . . . , L}, the length of the I^{th} information signal m_{I} may be represented as KI. That is, the I^{th} information signal m_{I} may be a vector having K_{I} elements.

The length of the information signals may vary. For example, |m₁|=2, |m₂|=2, and |m₃|=4.

The pre-transform unit 220 may include local pre-transform units corresponding to the number of divisions into which the bit splitting unit 210 divides the input signal m. According to an embodiment, the pre-transform unit 220 may include L local pre-transform units. The L remaining information signals m₁, . . . , and m_{L} may be transmitted to the L local pre-transform units, respectively. FIG. 2 illustrates three local pre-transform units 221 to 223 for brevity of explanation.

A pre-transform input signal v_{I}, which is an input signal of the I^{th} local pre-transform unit 222, may be represented by Equation 8.

$${v}_{l} = [ {v}_{l , {I}_{l}} , {v}_{l , {F}_{l}} ] \qquad [ Equation 8 ]$$

where, I_{I} indicates an I^{th} information index set. The number of elements of the I^{th} information index set I_{I} is |I₁|=K_{I}. F_{I} indicates an I^{th} frozen index set. v_{I,II} indicates one or more elements indicated by the I^{th} information index set I_{I} in the I^{th} pre-transform input signal V_{I}. V_{I,FI} indicates one or more elements indicated by the I^{th} frozen index set F_{I} in the I^{th} pre-transform input signal V_{I}.

The remaining information signals m_{I} may form a part of the pre-transform input signal v_{I}. The corresponding remaining information signal m_{I} may be assigned to one or more elements v_{I,II} indicated by the corresponding information index set I_{I} of the pre-transform input signal v_{I}. That is, m_{I} may be assigned to v_{I,II}, which may be represented by Equation 9.

$${v}_{l , {I}_{l}} = {m}_{l} \qquad [ Equation 9 ]$$

One or more frozen bits (that is, values known to both of the encoder and the decoder) may constitute a part of the pre-transform input signal v_{I}. The one or more frozen bits may be assigned to one or more remaining elements v_{I,FI} of the pre-transform input signal v_{I}. In other words, the frozen bits may be assigned to the one or more elements v_{I,FI} indicated by the corresponding frozen index set F_{I} of the pre-transform input signal v_{I}. According to an embodiment, a zero vector may be assigned to v_{I,FI}, which may be represented by Equation 10.

$${v}_{l , {F}_{l}} = 0 \qquad [ Equation 10 ]$$

For I∈{1, . . . ,L}, when the index set of the I^{th} pre-transform input signal v_{I} is [N_{I}], [N_{I}] may be represented by Equation 11.

$$[ {N}_{l} ] = {F}_{l} {⋃}_{{I}_{l}} \qquad [ Equation 11 ]$$

The local pre-transform units 221 to 223 may perform local pre-transformation in parallel with respect to the pre-transform input signals v1, . . . , and v_{L}. In other words, the 1^{st} local pre-transform unit 221 may perform the local pre-transformation with respect to the 1^{st} pre-transform input signal v₁, the I^{th} local pre-transform unit 222 may perform the local pre-transformation with respect to the I^{th} pre-transform input signal v_{I}, and the L^{th} local pre-transform unit 223 may perform the local pre-transformation with respect to the L^{th} pre-transform input signal V_{L}, wherein each local pre-transformation may be performed in parallel.

Each of the local pre-transform units 221 to 223 may perform the local pre-transformation by performing transformation using a pre-transform matrix. The connection signal u_{I} which is an output signal of the I^{th} local pre-transform unit 222 may be generated from the pre-transform matrix T_{I} corresponding to the pre-transform input signal V_{I} of the I^{th} local pre-transform unit 222. The connection signal u_{I} may be represented by Equation 12.

$${u}_{l} = {v}_{l} {T}_{l} \qquad [ Equation 12 ]$$

where, v_{I} is a 1×N_{I} vector, T_{I} is a N_{I}×N_{I} matrix, and u_{I} is a 1×N₁ vector.

According to an embodiment, the local pre-transform units 221 to 223 may use an upper-triangular matrix as the pre-transform matrix. For example, the pre-transform matrix T_{I} of the I^{th} local pre-transform unit 222 may be an upper-triangular matrix. As the local pre-transform units 221 to 223 use the upper-triangular matrix as the pre-transform matrix, the weight spectrum may be improved. For example, compared to when the local pre-transform is not used, the number of minimum-weight codewords may be reduced.

According to an embodiment, the pre-transform matrix of the local pre-transform units 221 to 223 may be a binary matrix. That is, the pre-transform matrix of the local pre-transform units 221 to 223 may be a matrix having 0 or 1 as an element.

According to an embodiment, the local pre-transform units 221 to 223 may use a transpose matrix of a polar transform matrix as the pre-transform matrix. For example, the pre-transform matrix T_{I} of the I^{th} local pre-transform unit 222 may be a transpose matrix of a polar transform matrix. In this case, Equation 12 may be represented by Equation 13.

$${u}_{l} = {v}_{l} {G}_{{N}_{l}}^{T} \qquad [ Equation 13 ]$$

where, G_{N}_{₁}^{T}, indicates the transpose matrix of the polar transform matrix G_{NI} of N_{I}×N_{I}.

According to an embodiment, the local pre-transform units 221 to 223 may use different pre-transform matrices. The local pre-transform units 221 to 223 may use the pre-transform matrices having different sizes. For example, the pre-transform matrix of the 1^{st} local pre-transform unit 221 and the pre-transform matrix of the 2^{nd} local pre-transform unit may have different sizes from each other. The local pre-transform units 221 to 223 may use the pre-transform matrices having different elements. For example, a value of an element of an i^{th} row and a j^{th} column of the pre-transform matrix T₁ of the 1^{st} local pre-transform unit 221 may be different from a value of an element of an i^{th} row and a j^{th} column of the pre-transform matrix of the 2^{nd} local pre-transform unit.

A polar transform input signal u₀, which is an input signal of the polar transform unit 230, may be represented by Equation 14.

$${u}_{0} = [ {u}_{0 , {F}_{0}} , {u}_{0 , {A}_{1}} , … , {u}_{0 {A}_{L}} , {u}_{0 , {I}_{0}} ] \qquad [ Equation 14 ]$$

where, for I∈{1, . . . , L}, A_{I} indicates an I^{th} connection index set.

The specific information signal m₀ may be assigned to one or more elements of the polar transform input signal u₀ indicated by the information index set I₀ of the specific information signal m₀. That is, m₀ may be assigned to u_{0,I0}, which may be represented by Equation 15.

$${u}_{0 , {I}_{0}} = {m}_{0} \qquad [ Equation 15 ]$$

For I∈{1, . . . , L}, the I^{th} connection signal u_{I} may be assigned to the one or more elements of the polar transform input signal u₀ indicated by the I^{th} connection index set A_{I}. That is, u_{I} may be assigned to u_{0,AI}, which may be represented by Equation 16.

$${u}_{0 , {{A}_{l}}^{=}} {u}_{l} \qquad [ Equation 16 ]$$

One or more frozen bits may be assigned to one or more remaining elements of the polar transform input signal u₀. That is, the one or more frozen bits may be assigned to the one or more remaining elements of the polar transform input signal u₀ indicated by the frozen index set F₀. This may be represented by Equation 17.

$${u}_{0 , {F}_{0}} = O \qquad [ Equation 17 ]$$

When the index set of the polar transform input signal u₀ is [N], [N] may be represented by Equation 18.

$$[ N ] = {F}_{0} ⋃ {I}_{0} ⋃ {A}_{0} \qquad [ Equation 18 ]$$

When a sparce pre-transform matrix T including the pre-transform matrices T₁, . . . , and T_{L} is used, the polar transform input signal u₀ may be represented by Equation 19.

$$[ Equation 19 ]$$

$$⌈ {u}_{0 {F}_{𝔬}} , {u}_{0 {A}_{1}} , … , {u}_{0 , {A}_{L}} , {u}_{0 , {I}_{0}} ⌉ = ⌈ 0 , {v}_{1} , … , {v}_{L} , {m}_{0} ⌉ [ \begin{matrix}I & 0 & 0 & 0 & 0 & 0 \\ 0 & {T}_{1} & 0 & 0 & 0 & 0 \\ 0 & 0 & 0 & ⋱ & 0 & 0 \\ 0 & 0 & 0 & ⋱ & {T}_{L} & 0 \\ 0 & 0 & 0 & ⋯ & 0 & I\end{matrix} ]$$

$$where T = [ \begin{matrix}I & 0 & 0 & 0 & 0 & 0 \\ 0 & {T}_{1} & 0 & 0 & 0 & 0 \\ 0 & 0 & 0 & ⋱ & 0 & 0 \\ 0 & 0 & 0 & ⋱ & {T}_{L} & 0 \\ 0 & 0 & 0 & ⋯ & 0 & I\end{matrix} ]$$

where, the sparse pre-transform matrix T is a block diagonal matrix, whereby the pre-transform matrices T₁, . . . , and T_{L} are located in a main diagonal block. I is an identity matrix.

The polar transform unit 230 may generate the output signal x by performing polar transformation on the polar transform input signal u₀. This may be represented by Equation 20.

$$x = {u}_{0} {G}_{N} \qquad [ Equation 20 ]$$

where, the polar transform matrix is G_{N}═ [symbol] and

$${G}_{2} = ⌊ \begin{matrix}1 & 1\end{matrix} ⌋ .$$

Two types of errors generating a decoding error of a successive cancellation list (SCL) decoder may be considered. The first error is that the correct decoding path is not in the final list. The second error is that the transmitted codeword is in the final list, but another codeword that is closer to the received signal is closer to the received message.

The encoder according to the present disclosure may use parallel local pre-transformation to minimize the loss of probability that the final list includes the correct decoding path (that is, to reduce the first error) and at the same time to improve the weight spectrum of the codeword (that is, to reduce the second error).

In detail, the encoder according to the present disclosure may reduce the first error by preventing, through the parallel local pre-transformation, the use of non-consecutive unreliable information bits. The pre-transform input signal of each local pre-transform unit may include one or more frozen bits, and thus, the connection signal of each local pre-transform unit may include nonconsecutive information bits. Thus, the polar transform unit 230 may perform polar transformation based on the nonconsecutive information bits of the connection signals u₁, . . . , and u_{L}. In detail, the pre-transform input signal of each local pre-transform unit may include one or more frozen bits, and the connection signal of each local pre-transform unit may be assigned to the polar transform input signal based on the corresponding connection index set. Thus, the number of consecutive information bits may be limited based on the size of each connection index set, that is, the size of each connection signal, in the connection signals u₁, . . . , and u_{L}. For example, in the connection signals u₁, . . . , and u_{L}, the number of consecutive information bits may be limited to |A_{I}|(=N_{I}), which is the size of each connection index set A_{I}, with respect to I∈{1, . . . , L}.

Also, through the parallel local pre-transformation, the encoder according to the present disclosure may appropriately swap the information bits with the frozen bits and use the information bits having a relatively low channel reliability as the connection signal to reduce the number of minimum-weight codewords. Thus, the second error may be reduced. With respect to this aspect, a method of selecting the information index set and the connection index set is described.

First, a method of selecting the I^{th} information index set I_{I} for the I^{th} pre-transform input signal v_{I} is described. The described method may be performed by at least one processor.

When the size of the pre-transform input signal v_{I} is N_{I}=2^{b}, the smaller b is, the more suitable it is for a small-sized SCL decoder, and the larger b is, the better the distance characteristics of the codeword can be. Based on this aspect, by appropriately selecting b, the size N_{I} of the pre-transform input signal v_{I} may be selected. According to an embodiment, the information index set I_{I} may be set as I_{I}={1,2, . . . , K_{I}}. where, K_{I} is a design parameter. For example, it may be set as K_{I}=N_{I}−1 or K_{I}=N_{I}−2. The I^{th} information index set I_{I} may be determined by various other methods.

Next, a method of the information index set I₀ and the connection index set A₀ (where,

$${A}_{0} = {{⋃}^{{L}^{…}}}_{l = 1} {A}_{l} )$$

for the polar transform input signal u₀ is described. The described method may be performed by at least one processor.

For brevity of explanation, an ordered index set R may be defined by Equation 21.

$$R = \{ {i}_{j} ∈ [ N ] : {i}_{1} , ⋯ , {i}_{{K}_{0} + {n}_{p}} \} \qquad [ Equation 21 ]$$

where, number of bits required for local pre-transformation and is

$${n}_{p} = {\sum }_{l = 1}^{{L}^{…}} {N}_{l} .$$

The ordered index set R is a sequence satisfying a first condition of wt(gᵢ)≥d^{min} and a second condition of

$$I ( {W}_{N}^{( {i}_{1} )} ) \geq I ( {w}_{N}^{( {i}_{2} )} ) \geq … \geq I ( {w}_{N}^{( {i}_{{K}_{0} + {n}_{p}} )} )$$

$$or$$

$$Z ( {W}_{N}^{( {i}_{1} )} ) \leq Z ( {W}_{N}^{( {i}_{2} )} ) \leq … \leq Z ( {W}_{N}^{( {i}_{{K}_{0} + {n}_{p}} )} )$$

with respect to all of i∈R. In the first condition, gᵢ indicates an i^{th} row of the polar transform matrix G_{N}. The first condition denotes that an i^{th} row-weight wt(gᵢ) of the polar transform matrix G_{N} is greater than or equal to a predetermined threshold value d^{min}. The second condition denotes that the order in which the reliability of the synthesized and separated channel W_{N}⁽ⁱ⁾ is sorted in descending order by polar transformation is not reversed.

The i^{th} bit channel W_{N}⁽ⁱ⁾ may be defined by Equation 22.

$${W}_{N}^{( i )} ( y , {u}_{1 : i - 1} \vert {u}_{i} ) = {\sum }_{{u}_{i + 1 : N} ∈ {\{ 0 , 1 \}}^{N - i}} \frac{1}{{2}^{N - I}} {W}^{N} ( y \vert x ) \qquad [ Equation 22 ]$$

where, W^{N}(y|x) indicates N copies of B-DMCs W(y|x). i∈[N].

The number of parity bits p may be determined based on Equation 23.

$$K + ρ = \vert {m}_{0} \vert + {\sum }_{l} {N}_{l} \qquad [ Equation 23 ]$$

By selecting K+ρ elements at the front having high channel reliability in the ordered index set R, an auxiliary set [symbol] may be generated. The predetermined number of elements, that is, |m₀| elements, according to the order of high channel reliability in the auxiliary set [symbol] may be assigned to the information index set I₀. Also, remaining elements in the auxiliary set [symbol] may be assigned to the connection index set A₀ (that is, A0= [symbol] \I₀). Lastly, each connection index set A_{I} may be set to satisfy the condition of Equation 24.

$$k ∈ {A}_{i} , l ∈ {A}_{j} ⇒ k < l \qquad [ Equation 24 ]$$

The local pre-transformations of the pre-transform unit 220 may be classified into a first type of local pre-transformation and a second type of local pre-transformation. The first type of local pre-transformation may correspond to the local pre-transformation described above. The second type of local pre-transformation may correspond to a transformation merging the information bit with the succeeding frozen bit. For example, the 1^{st} local pre-transform unit 221 may perform the first type of local pre-transformation, and the L^{th} local pre-transform unit 223 may perform the second type of local pre-transformation.

With respect to the pre-transform unit 220 performing L local pre-transformations in parallel, it is assumed that L₁ local pre-transformations of the first type are performed and L₂ local pre-transformations of the second type are performed (that is, L=L₁+L₂).

First, a method of designing the information index set I₀ and the connection index set A_{I} (where I∈[L_{I}]) for the first type of local pre-transformation is described. The described method may be performed by at least one processor.

The method of designing the information index set I₀ and the connection index set A_{I} for the first type of local pre-transformation may be substantially the same as the method of selecting the information index set I₀ and the connection index set A₀ described above.

The ordered index set R may be defined by Equation 25.

$$R = \{ {i}_{j} ∈ [ N ] : {i}_{1} , … , {i}_{{K}_{0} + {n}_{p}} \} \qquad [ Equation 25 ]$$

$$where$$

$$I ( {W}_{N} ) \geq I ( {W}_{N}^{( {i}_{1} )} ) \geq I ( {W}_{N}^{( {i}_{2} )} ) \geq … \geq I ( {W}_{N}^{( {i}_{{K}_{0} + {n}_{p}} )} )$$

$$and$$

$$I ( {W}_{N}^{( i )} ) > I ( {W}_{N}^{( j )} ) for any i ∈ R and j ∈ [ N ] \backslash R$$

The ordered index set R may be partitioned according to a row-weight of the polar transform matrix, as represented by Equation 26.

$$\begin{matrix}{B}_{w} ( R ) = \{ i ∈ R : wt ( {g}_{N , i} ) = w \} \\ = \{ {i}_{1}^{w} , {i}_{2}^{w} , … , {i}_{\vert {B}_{w} ( R ) \vert}^{w} \}\end{matrix} \qquad [ Equation 26 ]$$

where, among B_{w}(R), [symbol] indicates the least reliable index and [symbol] indicates the most reliable index. g_{N,i} is an i^{th} row of the N×N polar transform matrix.

When [symbol] ₘᵢₙ=min_{i∈R} [symbol] t(g_{N,i}), the auxiliary set [symbol] having the size nₚ and filled with indices included in B_{wmin}(R) may be generated. In detail, an index corresponding to the least reliable bit may be included in the auxiliary set [symbol] . When the number of elements of the auxiliary set [symbol] is less than nₚ, a process of using a next largest row weight index set B_{2wmin}(R) may be repeated, to generate the auxiliary set [symbol] .

The information index set I₀ may be generated from the auxiliary set [symbol] as represented by Equation 27.

$${I}_{0} = R ∖$$

Thereafter, the elements of the auxiliary set [symbol] may be re-ordered according to a naturally ascending sequence. This may be represented by Equation 28.

$$= \{ , … , \} , where < for j < u \qquad [ Equation 28 ]$$

The I^{th} connection index set A_{I} may be generated by using the re-ordered auxiliary set [symbol] as represented by Equation 29.

$${A}_{l} = \{ {{\sum }_{j = 1}^{l - 1} {N}_{j} + 1}_{} , … , {{\sum }_{j = 1}^{l} {N}_{j} + 1}_{} \} for l ∈ [ {L}_{1} ] \qquad [ Equation 29 ]$$

Additionally, the I^{th} information index set I_{I} may be generated by Equation 30.

$${I}_{l} = \{ i ∈ [ {N}_{l} ] : {i}_{1} , … , {i}_{{K}_{l}} \} \qquad [ Equation 30 ]$$

$$where wt ( {g}_{{i}_{1} , {N}_{l}}^{T} ) \geq w t ( {g}_{{i}_{2} , {N}_{l}}^{T} ) \geq … \geq w t ( {g}_{{i}_{{K}_{i}} , {N}_{l}}^{T} )$$

Next, a method of designing the connection index set A_{I} (where I∈[L₂]) for the second type of local pre-transformation is described. The described method may be performed by at least one processor.

Given a pair of an index i included in the information index set and an index j included in the subsequent frozen index set, the pre-transform unit 220 may perform the second type of local pre-transformation on elements indicated by the corresponding pair. For the second type of local pre-transformation, G₂^{T} may be used as the pre-transform matrix. That is, the second type of local pre-transformation may correspond to a row-merging operation.

The pair i,j may be selected for the purpose of merging the information bits with the suceeding frozen bits, in order to reduce the number of minimum-weight codewords.

The notation may be defined by Equation 31 and Equation 32.

$${w}_{min} ( I ) \dot{=} \begin{matrix}mmi \\ i ∈ I\end{matrix} wt ( {g}_{N , i} ) \qquad [ Equation 31 ]$$

$${B}_{w} ( I ) \dot{=} \{ i ∈ I : wt ( {g}_{N , i} ) = w \} \qquad [ Equation 32 ]$$

Also, an I^{th} pair M_{I} may be represented by Equation 33.

$${M}_{l} = ( {M}_{l , 1} , {M}_{l , 2} ) \qquad [ Equation 33 ]$$

where, M_{I,1} indicates the information index and M_{I,2} indicates the merged frozen index.

When the information index i∈B_{wmin}(I₀) and the predetermined merged pair M_{I} are given, a candidate Pi of the merged frozen index may be represented by Equation 34.

$${P}_{i} \dot{=} \{ j ∈ [ N ] ∖ [ i ] : j ∉ {A}_{l} ⋃ {I}_{0} , j ∉ {M}_{l , 2} \} \qquad [ Equation 34 ]$$

This denotes that all of subsequent frozen indices not included in the first type of local pre-transformation may become the candidate Pi of the merged frozen index.

With respect to the information index i∈B_{wmin}(I₀), when Equation 35 is satisfied, j∈Pⱼ may be selected as the merged frozen index.

$$t ( {g}_{N , j} ) \geq {min}_{} \qquad [ Equation 35 ]$$

Next, for the information index i∈B_{wmin}(I₀))\(∪_{I}M_{I,1}), when Equation 36 is satisfied, j∈Pⱼ may be selected as the merged frozen index.

$$t ( {g}_{N , i} + {g}_{N , j} ) > {min}_{} \qquad [ Equation 36 ]$$

Finally, j∈Pⱼ, which satisfies Equation 37, may be selected as the merged frozen index.

$$t ( {g}_{N , i} + {g}_{n , j} ) = {min}_{} \qquad [ Equation 37 ]$$

As described above, the second type of local pre-transformation may be performed on the determined pair i,j, and thus, the number of minimum-weight codewords may be reduced.

As described above, the information index set and the connection index set are determined, and thus, the first error and the second error may be improved. In detail, the information index set and the connection index set may be determined by taking into account the channel reliability and the minimum-weight rows, and thus, the information bits and the frozen bits may be properly exchanged. Thus, the probability loss of including the correct decoding path in the final list may be minimized (that is, the first error may be reduced), and at the same time, the number of minimum-weight codewords may be reduced, and thus, the weight spectrum of the codeword may be improved (that is, the second error may be reduced).

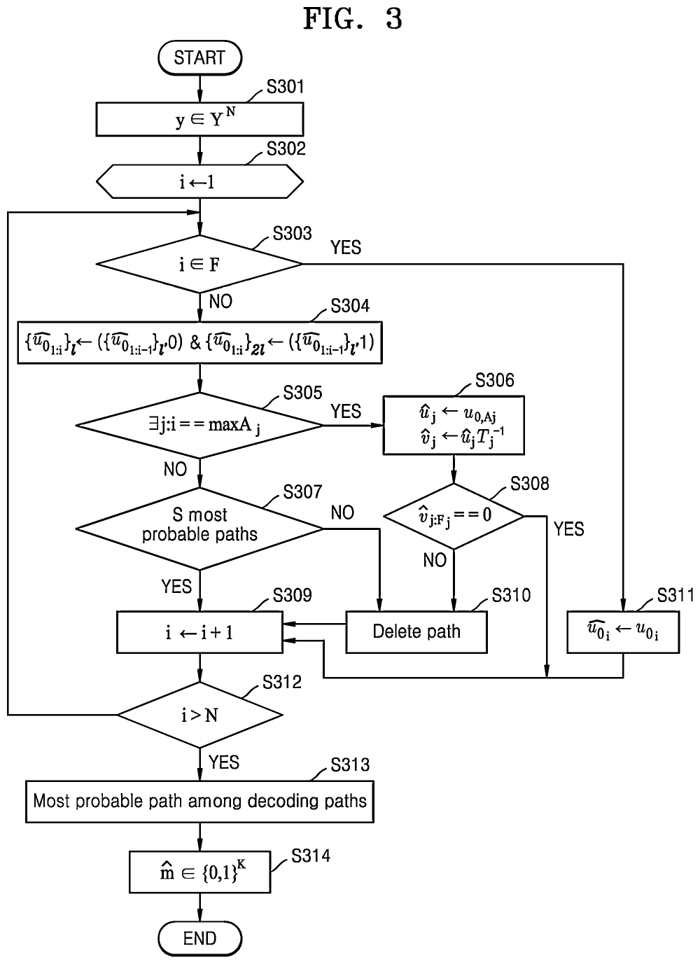

FIG. 3 illustrates a decoding process according to an embodiment.

When a codeword encoded by the transmitter 110 (FIG. 1) is received by the receiver 130 (FIG. 1) through a channel, the receiver may perform decoding to reconstruct the received message \hat{m} from a received signal y. The decoder 112 (FIG. 1) may decode the input signal u₀ of the polar transformation according to the order from the first element to the last element, by using channel polarization obtained by the polar transformation.

The decoder may sequentially search for decoding paths with respect to the received signal y and select the final decoding path from among the decoding paths to generate the received message \hat{m} corresponding to the received signal y. Here, the number of decoding paths may not exceed a predetermined number.

The decoder may include an SCL decoder.

The decoder may perform the same process on each element. Thus, for brevity of explanation, a process in which the decoder decodes an i^{th} element is described.

When the decoder decodes the i^{th} element, the decoding may be performed by referring to the received signal y and previously decoded elements [symbol] =[ [symbol] , . . . , [symbol] ]. It is assumed that the decoder may have S hypotheses, at most, with respect to the previously decoded elements. An I^{th} hypothesis is to be noted as { [symbol] }ₗ and is to be referred to as a decoding path.

In operation S301, the decoder may receive the codeword y through the channel.

In operation S302, the decoder may perform decoding firstly on a first element i←1 of the codeword y.

In operation S303, the decoder may identify whether or not the i^{th} element is a frozen bit with respect to each candidate.

In operation S303, when it is determined to be YES, the process may proceed to operation S311 and a value u₀_{ᵢ} shared with the encoder may be assigned to the i^{th} element [symbol] . Next, the process may proceed to operation S309 to perform decoding of the i+1^{th} element

When it is determined to be NO in operation S303, the process may proceed to operation S304, and a current decoding path may be copied and the i^{th} element may be assumed to be 0 and 1, to generate the decoding path.

Next, the decoder may perform a process of reducing the decoding paths.

In operation S305, the decoder may determine whether i is included in the connection index set A_{I} and corresponds to the maximum value of the elements of the connection index set A_{I}.

When it is determined to be YES in operation S305, the local pre-transformation Tⱼ corresponding to the connection index set Al may be inversely transformed to check whether or not a current path is a valid path. In detail, in operation S306, an element ûⱼ corresponding to the output of the local pre-transformation Tⱼ may be inversely transformed to obtain an input element \hat{v}ⱼ , and in operation S308, whether or not a frozen bit \hat{v}_{j,F}_{ⱼ} of the input element corresponds to a predetermined value may be checked.

When it is determined to be YES in operation S308, the process may proceed to operation S309 and the decoding may be performed on the next element.

When it is determined to be NO in operation S308, the process may proceed to operation S310, and all but the S most probable decoding paths are removed from the hypothesis, and the process proceeds to operation S309 to decode the next element.

When it is determined to be NO in operation S305, the process may proceed to operation S307 to determine whether there are S decoding paths. When there are more than S decoding paths, the process may proceed to operation S310, and all but the S most probable decoding paths are removed from the hypothesis, and the process proceeds to operation S309 to decode the next element. When there are not more than S decoding paths, the process may proceed to operation S309 to decode the next element.

In operation S312, the decoder may repeat the described process.

In operation S313, the decoder may select the most probable decoding path from among the S decoding paths obtained by decoding up to the last element, and thus, may reconstruct the received message \hat{m} in operation S314.

The decoder may decode the codeword x encoded based on the parallel local pre-transformation and the polar transformation, and thus, the elements [symbol] corresponding to the input signal of the polar transformation of the encoder obtained in the decoding process may include the non-consecutive information bits.

The described method may be recorded on a computer-readable recording medium having recorded thereon one or more programs including instructions for executing the method. Examples of the computer-readable recording medium include magnetic media (e.g., hard discs, floppy discs, or magnetic tapes), optical media (e.g., compact disc-read only memories (CD-ROMs), or digital versatile discs (DVDs)), magneto-optical media (e.g., floptical discs), and hardware devices that are specially configured to store and carry out program commands (e.g., ROMs, random-access memories (RAMs), or flash memories). Examples of the program instructions include a high-level language code executable by a computer by using an interpreter, etc., as well as a machine language code, such as the one made by a complier.

The present disclosure is described above as examples, and it would be understood by one of ordinary skill in the art that the present disclosure may be easily modified as other specific forms without changing the technical concept or essential features of the present disclosure. Hence, it will be understood that the embodiments described above are examples in all aspects and are not limiting of the scope of the present disclosure. For example, each of components described as a single unit may be executed in a distributed fashion, and likewise, components described as being distributed may be executed in a combined fashion.

The scope of the present disclosure is indicated by the claims rather than by the detailed description of the disclosure, and it should be understood that the claims and all modifications or modified forms drawn from the concept of the claims are included in the scope of the disclosure.

According to embodiments of the present disclosure, low-complexity decoding for improving the distance characteristic of the polar code through local pre-transformation in a limited block length and using channel polarization may be possible.

Also, according to embodiments of the present disclosure, a foundation technique appropriate for low-latency and high-reliability communication required for next generation communication systems may be provided.

Also, according to embodiments of the present disclosure, a method of designing a pre-transformation polar code appropriate for the low-complexity decoding (for example, successive cancellation (SC)-type decoding, but not limited thereto) using the channel polarization, may be provided.

Also, according to embodiments of the present disclosure, pre-transformation using an upper-triangular matrix may be locally used for a group of carefully selected bits, and thus, the distance characteristic of a codeword may be improved. Also, it may be prevented to discard a correct decoding path in the SC-type decoding.

The effects which may be obtained by the exemplary embodiments of the present disclosure are not limited to the effects described above, and other effects not described may be clearly derived and understood by one of ordinary skill in the art from the descriptions of the exemplary embodiments of the present disclosure hereinafter. That is, the effects not intended but generated by the exemplary embodiments of the present disclosure may also be derived by one of ordinary skill in the art from the exemplary embodiments of the present disclosure.

What is claimed is:

1. An encoder using local pre-transformation, the encoder comprising:
a bit splitting unit configured to generate a specific information signal and remaining information signals by splitting an input signal;
a pre-transform unit configured to generate connection signals by performing, in parallel, local pre-transformation, based on each of the remaining information signals; and
a polar transform unit configured to generate an output signal by performing polar transformation, based on the specific information signal and the connection signals.

2. The encoder of claim 1, wherein
the polar transform unit is further configured to
perform the polar transformation, based on the specific information signal and non-consecutive information bits of the connection signals, and
to obtain the output signal from a result of the polar transformation.

3. The encoder of claim 1, wherein
a number of consecutive information bits of the connection signals is limited based on a size of each connection signal.

4. The encoder of claim 1, wherein
the pre-transform unit comprises local pre-transform units, and
each of the local pre-transform units
is configured to generate the connection signal by performing the local pre-transformation using an upper-triangular matrix, based on a corresponding remaining information signal.

5. The encoder of claim 1, wherein
the pre-transform unit comprises local pre-transform units, and
each of the local pre-transform units
is configured to generate a pre-transform input signal by adding one or more frozen bits to a corresponding remaining information signal and
to generate the connection signal by performing the local pre-transformation on the pre-transform input signal.

6. The encoder of claim 5, wherein,
as the one or more frozen bits are added to the corresponding remaining information signal, the connection signal comprises non- consecutive information bits.

7. The encoder of claim 5, wherein
each of the local pre-transform units
is further configured to assign the corresponding remaining information signal to one or more elements of the pre-transform input signal indicated by a corresponding information index set and
to assign the one or more frozen bits to one or more remaining elements of the pre-transform input signal.

8. The encoder of claim 1, wherein
the polar transform unit is further configured to
generate a polar transform input signal comprising the specific information signal, the connection signals, and one or more frozen bits and
to generate the output signal by performing polar transformation on the polar transform input signal.

9. The encoder of claim 8, wherein
the polar transform unit is further configured to
assign the specific information signal to one or more elements of the polar transform input signal indicated by a corresponding information index set,
assign a corresponding connection signal to one or more elements of the polar transform input signal indicated by a connection index set, and
assign the one or more frozen bits to one or more remaining elements of the polar transform input signal.

10. The encoder of claim 9, wherein
the information index set and the connection index set comprise, from among total indices of the polar transform input signal, indices having high channel reliability and having a corresponding row-weight of a polar transformation matrix greater than or equal to a predetermined threshold value.

11. An encoding method using local pre-transformation, the encoding method comprising:
generating a specific information signal and remaining information signals by splitting an input signal;
generating connection signals by performing, in parallel, local pre- transformation, based on each of the remaining information signals; and
generating an output signal by performing polar transformation, based on the specific information signal and the connection signals.

12. The encoding method of claim 11, wherein
the generating of the output signal comprises:
performing the polar transformation, based on the specific information signal and non-consecutive information bits of the connection signals; and
obtaining the output signal from a result of the polar transformation.

13. The encoding method of claim 11, wherein
a number of consecutive information bits of the connection signals is limited based on a size of each connection signal.

14. The encoding method of claim 11, wherein
the generating of the connection signals comprises
obtaining the connection signals by performing, in parallel, the local pre- transformation using an upper-triangular matrix, based on each of the remaining information signals.

15. The encoding method of claim 11, wherein
the generating of the connection signals comprises:
generating pre-transform input signals by adding one or more frozen bits to the remaining information signals, respectively; and
generating the connection signals by performing, in parallel, the local pre-transformation on each of the pre-transform input signals.

16. The encoding method of claim 15, wherein,
as the one or more frozen bits are added to the remaining information signals, respectively, the connection signals comprise non-consecutive information bits, respectively.

17. The encoding method of claim 15, wherein
the generating of the pre-transform input signals comprises
assigning a corresponding remaining information signal to one or more elements of a pre-transform input signal indicated by a corresponding information index set and
assigning the one or more frozen bits to one or more remaining elements of the pre-transform input signal.

18. The encoding method of claim 11, wherein
the generating of the output signal comprises
generating a polar transform input signal comprising the specific information signal, the connection signals, and one or more frozen bits and
generating the output signal by performing polar transformation on the polar transform input signal.

19. The encoding method of claim 18, wherein
the generating of the polar transform input signal comprises:
assigning the specific information signal to one or more elements of the polar transform input signal indicated by a corresponding information index set;
assigning a corresponding connection signal to one or more elements of the polar transform input signal indicated by a connection index set; and
assigning the one or more frozen bits to one or more remaining elements of the polar transform input signal.

20. A decoding method comprising:
receiving an input signal; and
generating an output signal corresponding to the input signal by sequentially searching for decoding paths with respect to the input signal and selecting a final decoding path from among the decoding paths,
wherein a number of the decoding paths does not exceed a predetermined number, and
the input signal corresponds to a codeword encoded based on parallel local pre-transformation and polar transformation.
